(19) United States
(12) Patent Application Publication
(10) Pub. No.: US 2015/0060794 A1
(43) Pub. Date: Mar. 5, 2015

(54) ORGANIC LIGHT EMITTING DEVICE AND MANUFACTURING METHOD THEREOF

(71) Applicant: SAMSUNG DISPLAY CO., LTD., Yongin-City (KR)

(72) Inventors: Eon Seok OH, Yongin-City (KR); Sol Ji KIM, Yongin-City (KR); Min Seong YI, Yongin-City (KR); Bo Mi CHOI, Yongin-City (KR)

(21) Appl. No.: 14/310,118

(22) Filed: Jun. 20, 2014

(30) Foreign Application Priority Data
Sep. 4, 2013 (KR) 10-2013-0106224

(51) Int. Cl. H01L 51/56; H01L 51/50

(52) U.S. Cl. CPC H01L 51/56; H01L 51/5008
USPC 257/40; 438/34

(57) ABSTRACT

An organic light emitting device includes an anode, a cathode, and an organic layer between the anode and the cathode, wherein the organic layer includes an emission layer, an electron transport layer, and an assistance layer interposed therebetween, and the assistance layer has a higher HOMO level than the electron transport layer by more than 0.3 eV. The accumulation of holes in the electron transport layer is decreased or prevented by the gap of the HOMO level between the assistance layer and the electron transport layer such that the lifetime of the organic light emitting device may be increased.

### CROSS-REFERENCE TO RELATED APPLICATION

Korean Patent Application No. 10-2013-0106224, filed on Sep. 4, 2013, in the Korean Intellectual Property Office, and entitled: “Organic Light Emitting Device and Manufacturing Method Thereof,” is incorporated by reference herein in its entirety.

### BACKGROUND

1. Field

Embodiments relate to an organic light emitting device and a manufacturing method thereof.

2. Description of the Related Art

Because lightweight and thin display devices are now required for monitors and televisions, cathode ray tube (CRT) display devices are disappearing and are being replaced by flat panel displays (FPD). The application field has simultaneously spread into mobile devices. Among flat panel displays, liquid crystal displays (LCDs) have recently been most widely used, and because the liquid crystal display is a non-emissive display device, a separate light source such as a backlight is required. There are also limitations to LCD response speed and viewing angle.

Recently, as a display to address these limitations, organic light emitting diode (OLED) displays are being developed. OLED displays are self-luminous display devices that may have a wide viewing angle, an excellent contrast ratio, and a fast response time.

The above information disclosed in this Background section is only for enhancement of understanding of the background and therefore it may contain information that does not constitute prior art.

### SUMMARY

An organic light emitting device according to exemplary embodiments may include an anode, a cathode, and an organic layer between the anode and the cathode, wherein the organic layer includes an emission layer, an electron transport layer, and an assistance layer interposed between the emission layer and the electron transport layer. The assistance layer may have a HOMO level more than 0.3 eV higher than a HOMO level of the electron transport layer.

The assistance layer may include 26DCzPPy (2,6-bis(3-(9H-carbazol-9-yl)phenyl)pyridine) and/or CBzCBI (9-phenyl-3-(4-(1-phenyl-1H-benzo[d]imidazol-2-yl)phenyl)-9H-carbazole).

The assistance layer may be doped with at least one dopant at a ratio of about 5% to about 95% by weight.

The dopant may be selected from a group including TPBi (2,2′,2″-(1,3,5-benzinetriyl)-tris(1-phenyl-1-H-benzimidazole)), Liq (8-hydroxyquinolinolato-lithium), NBphen (2,9-bis(naphthalen-2-yl)-4,7-diphenyl-1,10-phenanthroline), 2-NPIP (1-methyl-2-(4-(naphthalen-2-yl)phenyl)-1H-imidazo[4,5f][1,10]phenanthroline), and TmPPPyTz (2,4,6-tris(3′-(pyridin-3-yl)biphenyl-3-yl)-1,3,5-triazine).

The organic layer may further include a hole injection layer and a hole transport layer between the anode and the emission layer.

The organic layer may further include an electron injection layer between the cathode and the electron transport layer.

The assistance layer may have a higher LUMO level than a LUMO level of the electron transport layer, and the assistance layer may have a lower LUMO level than a LUMO level of the emission layer.

The assistance layer may have lower hole mobility than the emission layer.

Embodiment are directed to a manufacturing method of an organic light emitting device according to an exemplary embodiment including: forming an anode on a substrate; forming a hole injection layer and a hole transport layer on the anode; forming an emission layer on the hole transport layer; forming an assistance layer on the emission layer; forming an electron transport layer on the assistance layer; and forming a cathode on the electron transport layer. The assistance layer may have a HOMO level more than 0.3 eV higher than a HOMO level of the electron transport layer.

The assistance layer may be separately formed before the forming of the electron transport layer.

Forming the assistance layer may include initially doping a portion of the electron transport layer with a dopant to form the assistance layer as a portion of the electron transport layer.

The dopant may be selected from a group including TPBi (2,2′,2″-(1,3,5-benzinetriyl)-tris(1-phenyl-1-H-benzimidazole)), Liq (8-hydroxyquinolinolato-lithium), NBphen (2,9-bis(naphthalen-2-yl)-4,7-diphenyl-1,10-phenanthroline), 2-NPIP (1-methyl-2-(4-(naphthalen-2-yl)phenyl)-1H-imidazo[4,5f][1,10]phenanthroline), TmPPPyTz (2,4,6-tris(3′-(pyridin-3-yl)biphenyl-3-yl)-1,3,5-triazine).

The manufacturing method may further include forming an electron injection layer before forming the cathode.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a deposition structure of an organic light emitting device according to an exemplary embodiment.

FIG. 2 illustrates a view showing a HOMO level relation between predetermined layers in an organic light emitting device according to a conventional art and the organic light emitting device according to the exemplary embodiment of FIG. 1.

FIG. 3 illustrates a view showing an energy level relationship between layers in an organic light emitting device according to a conventional art.

FIG. 4 illustrates a view showing an energy level relation between layers in an organic light emitting device according to Experimental Example 1.

FIG. 5 to FIG. 9 illustrate views showing a lifetime of an organic light emitting device according to a conventional art and an organic light emitting device according to experimental examples.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

An organic light emitting device according to an exemplary embodiment will now be described in detail with reference to the accompanying drawings.

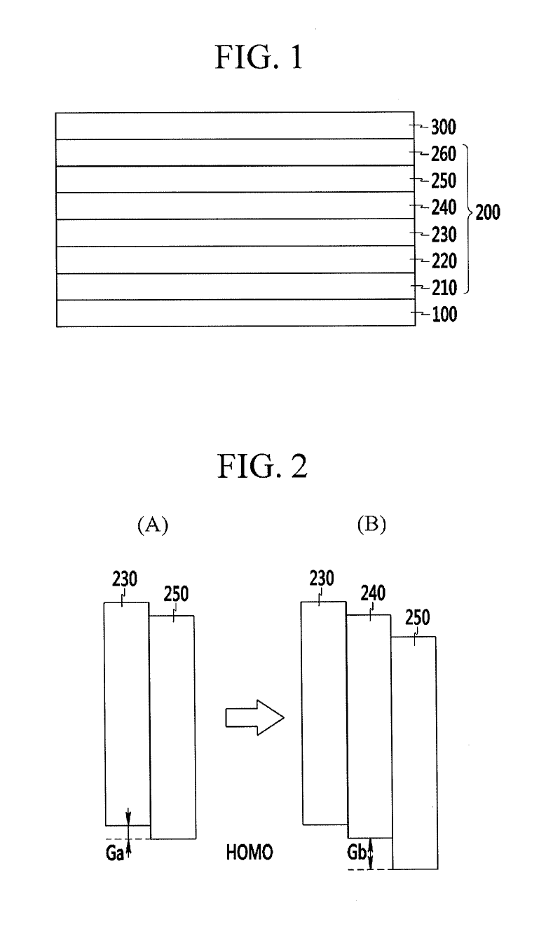

FIG. 1 illustrates a cross-sectional view of a deposition structure of an organic light emitting device according to an exemplary embodiment.

Referring to FIG. 1, an organic light emitting device according to the present exemplary embodiment includes an organic layer 200 between a pair of electrodes including an anode 100 and a cathode 300. The substrate (not shown) may be disposed on a side of the anode 100 or the cathode 300. The substrate may include glass, polymer, or combinations thereof.

The anode 100 may be formed of a material having high transmittance, low sheet resistance, and a good manufacturing processability. For example, the anode 100 may be formed of a transparent conductive material such as indium tin oxide (ITO) and indium zinc oxide (IZO). Also, according to a light emitting direction of the organic light emitting device, a conductive reflection layer and an additional transparent conductive layer may be further included on the transparent conductive material. The reflection layer may improve electrical conductivity while increasing light emitting efficiency, and for example, aluminum (Al), an aluminum alloy (Al alloy), silver (Ag), a silver alloy (Ag alloy), gold (Au), or a gold alloy (Au alloy) may be used. The additional transparent conductive layer may suppress oxidation of the reflection layer and may be made of ITO or IZO.

The cathode 300 may be made of the transparent conductive material like the anode 100, and for example, ITO, IZO, SnO, or ZnO may be used. On the other hand, the cathode 300 may be formed of a transparent or a reflective metal thin film, for example lithium (Li), magnesium (Mg), aluminum (Al), aluminum-lithium (Al—Li), calcium (Ca), magnesium-indium (Mg—In), magnesium-silver (Mg—Ag), calcium (Ca)-aluminum (Al), however it is not limited thereto.

The anode 100 and the cathode 300 may be formed of a material that does not inject the holes to the organic layer 200 when an inverse-direction bias is applied to the organic light emitting device.

The organic layer 200 may include a hole injection layer 210, a hole transport layer 220, an emission layer 230, an assistance layer 240, an electron transport layer 250, and an electron injection layer 260.

The hole injection layer 210 and the hole transport layer 220 are disposed between the anode 100 and the emission layer 230 such that the holes may be easily transmitted from the anode 100 to the emission layer 230. The hole injection layer 210 and the hole transport layer 220 may be separated from each other or may be formed into one layer.

The hole injection layer 210 may be made of a hole injection material. For example, the hole injection material may be a phthalocyanine compound such as copper phthalocyanine or the like, m-MTDATA (4,4′,4″-tris(3-methylphenylphenylamino)triphenylamine), NPB (N,N′-di(1-naphthyl)-N,N′-diphenylbenzidine), TDATA, 2T-NATA, PANI/DBSA (polyaniline/dodecylbenzene sulfonic acid), PEDOT/PSS (poly(3,4-ethylene dioxythiophene)/poly(4-styrene sulfonate), PANI/CSA (polyaniline/camphor sulfonic acid), or PANI/PSS (polyaniline/poly(4-styrene sulfonate)), but is not limited thereto.

Also, the hole transport layer 220 may include a well-known hole transport material. For example, the hole transport material may be a carbazole derivative such as N-phenylcarbazole, polyvinylcarbazole, or the like, or an amine derivative having an aromatic condensed ring such as NPB, N,N′-bis(3-methylphenyl)-N,N′-diphenyl-[1,1-biphenyl]-4,4′-diamine (TPD), or the like.

The emission layer 230 may be formed of an organic material emitting red, green, or blue light.

When the emission layer 230 is formed of the organic material emitting red light, DCM1 (4-(dicyanomethylene)-2-methyl-6-(p-dimethylaminostyryl)-4H-pyran), DCM2 (2-methyl-6-[2-(2,3,6,7-tetrahydro-1H,5H-benzo[ij]quinolizin-9-yl)ethenyl]-4H-pyran-4-ylidene]propane dinitrile), Eu(TTA)₃ (Eu(thenoyltrifluoroacetone)₃), or butyl-6-(1,1,7,7-tetramethyljulolidyl-9-enyl)-4H-pyran (DCJTB) may be used. On the other hand, as the organic material emitting red light, a material of which a dopant such as DCJTB is doped to Alg₃ or a material of which Alg₃ and rubrene are co-deposited and the dopant is doped may be used. Also, as the organic material emitting red light, a material in which a dopant such as BtpIr or Ir(piq)₃ is doped to 4,4′-N—N′-dicarbazole-biphenyl (CBP) may be used.

When the emission layer 230 is formed of the organic material emitting green, coumarin 6, C545T, quinacridone, or Ir(ppy)₃ may be used. On the other hand, as the organic material emitting green light, a material in which an Ir(ppy)₃ dopant is doped to CBP (4,4′-bis(carbazol-9-yl)biphenyl) or a material in which a coumarin-based dopant is doped to Algₐ as a host can be used, however it is not limited thereto. The coumarin-based dopant may be C314S, C343S, C7, C7S, C6, C6S, C314T, or C545T.

When the emission layer 230 is formed of the organic material emitting blue light, oxadiazole dimer dyes (bis-DAPDXP), spiro compounds (spiro-DPVBi, spiro-6P), triarylamine compounds, bis(styryl)amine (DPVBi, DSA), Flr(pic), CzTT, anthracene, TPB, PPCP, DST, TPA, OXD-4, BBOT, AZM-Zn, or BH-013X (Idemitsu company) as an aromatic hydrocarbon compound including a naphthalene moiety may be used. On the other hand, as the organic material emitting blue light, a material in which a dopant such as IDE140, IDE105 (Idemitsu company) is doped may be used, however it is not limited thereto. Also, a material in which a dopant such as DPASN ((E)-6-(4-(diphenylamino)styryl)-N,N-diphenylnaphthalen-2-amine) is doped to a host such as ADN (9,10-di(naphth-2-yl)anthracene) may be used.

The assistance layer 240 and the electron transport layer 250 are disposed on the emission layer 230. The organic light emitting device according to an exemplary embodiment may have a structure in which an assistance layer 240 is formed between the emission layer 230 and the electron transport layer 250. The assistance layer 240 may prevent or substantially prevent holes from being accumulated in the electron transport layer 250. In other words, the assistance layer 240 may reduce an amount of holes accumulated in the electron transport layer 250.

The electron transport layer 250 may easily inject electrons from the cathode 300 to the emission layer 230. The electron transport layer 250 may be formed of an electron transport material. The electron transport material may include quinoline derivatives, for example, Alg₃ (aluminum tris(8-hydroxyquinoline)), TAZ, or Balq, but is not limited thereto. Also, the electron transport layer 250 may include Li, Cs, Mg, LiF, CsF, MgF₂, NaF, KF, BaF₂, CaF₂, Li₂O, BaO, Cs₂CO₃, Cs₂O, CaO, MgO, or lithium quinolate.

The assistance layer 240 may be formed of a material creating a HOMO level gap between the emission layer 230 and the electron transport layer 250 when the assistance layer 240 is larger than a HOMO level gap between the emission layer 230 and the electron transport layer 250 in absence of the assistance layer 240. The HOMO level of the assistance layer 240 may be higher than the HOMO level of the electron transport layer 250. For example, the HOMO level of the assistance layer 240 may be more than about 0.3 eV higher than the HOMO level of the electron transport layer 250.

The assistance layer 240 may be formed of a material including at least one of 26DCzPPy (2,6-bis(3-(9H-carbazol-9-yl)phenyl)pyridine) and CBzCBI (9-phenyl-3-(4-(1-phenyl-1H-benzo[d]imidazol-2-yl)phenyl)-9H-carbazole). The assistance layer 240 may include at least one dopant. The dopant may include at least one of TPBi (2,2′,2″-(1,3,5-benzinetriyl)-tris(1-phenyl-1-H-benzimidazole)), Liq (8-hydroxyquinolinolato-lithium), NBphen (2,9-bis(naphthalen-2-yl)-4,7-diphenyl-1,10-phenanthroline), 2-NPIP (1-methyl-2-(4-(naphthalen-2-yl)phenyl)-1H-imidazo[4,5f][1,10]phenanthroline), and TmPPPyTz (2,4,6-tris(3′-(pyridin-3-yl)biphenyl-3-yl)-1,3,5-triazine).

The assistance layer 240 may be formed by depositing only a material including at least one of 26DCzPPy and CBzCBI, or may be formed by doping a dopant in the material. The electron transport layer 250 may be deposited directly on the emission layer 230, and the dopant may be doped at the initial time of the depositing such that a portion of the electron transport layer 250 contacting or adjacent to the emission layer 230 may form the assistance layer 240. In some embodiments, the dopant may be doped at a ratio of about 5 to about 95% by weight.

In exemplary embodiments a LUMO level of the assistance layer 240 may be between the LUMO level of the emission layer 230 and the LUMO level of the electron transport layer 250; however, the LUMO level of the assistance layer 240 may be higher than the LUMO level of the emission layer 230 or may be lower than the LUMO level of the electron transport layer 250.

In another exemplary embodiment, the assistance layer 240 may have a lower hole mobility than the electron transport layer 250. The speed of the holes flowing from the emission layer 230 into the electron transport layer 250 may be decreased by the assistance layer 240 having the low hole mobility such that the accumulation rate of the holes in the electron transport layer 250 is decreased, thereby increasing the lifetime of the organic light emitting device. In other words, the assistance layer 240 may reduce a rate of migration of holes from the emission layer 230 to the electron transport layer 250.

On the other hand, the electron injection layer 260 may be disposed such that the electrons between the electron transport layer 250 and the cathode 300 may be easily injected from the second electrode 300 to the emission layer 230, and the electron injection layer 260 may be omitted according to an exemplary embodiment. The electron injection layer 260 may be formed of an electron injection material. This material may be lithium fluoride, lithium quinolate (Liq), oxadiazole, triazole, or triazine, but is not limited thereto.

FIG. 2 illustrates a view showing a HOMO level relationship between predetermined layers in an organic light emitting device according to a conventional device and the organic light emitting device according to the exemplary embodiment of FIG. 1.

In FIG. 2, the left drawing (A) illustrates a conventional organic light emitting device. Drawing (A) illustrates a device having a structure where the electron transport layer 250 is deposited directly on the emission layer 230. In this structure, a gap (Ga) of the HOMO level between the emission layer 230 and the electron transport layer 250 may be less than about 0.2 eV, for example, 0.1-0.2 eV, or there may be no gap. In the gap (Ga) of the HOMO level, when the organic light emitting device is driven, holes may flow excessively from the emission layer 230 to the electron transport layer 250. The holes may accumulate inside the electron transport layer 250, resulting in the electron transport layer 250 losing some or all of its character as an electron transport layer. The accumulation of holes in the electron transport layer may shorten the lifetime of the organic light emitting device.

In FIG. 2, the right drawing (B) illustrates the organic light emitting device of FIG. 1, and has a structure where the assistance layer 240 is deposited between the emission layer 230 and the electron transport layer 250. The gap (Gb) of the HOMO level between the assistance layer 240 and electron transport layer 250 may be larger than the gap (Ga) of the described HOMO level, and may be about 0.3 eV. The gap (Gb) of the HOMO level increased by the assistance layer 240 may reduce or prevent the accumulation of the holes from the emission layer 230 in the electron transport layer 250. In this embodiment, a large gap (Gb) may be advantageous, however the electrical characteristics of the organic light emitting device may be deteriorated. Accordingly, the gap (Gb) may be less than about 0.5 eV, however this is only an example, and the gap Gb) is not limited thereto.

In some embodiments, the HOMO level between the emission layer 230 and the assistance layer 240 is slightly higher on the side of the emission layer 230, however the side of the assistance layer 240 may be slightly higher, or both sides may be the same or about the same.

The following Examples and Comparative Examples are provided in order to highlight characteristics of one or more embodiments, but it will be understood that the Examples and Comparative Examples are not to be construed as limiting the scope of the embodiments. Further, it will be understood that the embodiments are not limited to the particular details described in the Examples and Comparative Examples.

### Experimental Example 1

An anode of ITO was formed, a hole injection layer of 2T-NATA was formed thereon, and then a hole transport layer of NPB was formed thereon. A blue emission layer of EMLADN:DPASN was formed on the hole transport layer, and an assistance layer AL of CBzCBI was formed thereon. The electron transport layer ETL of TPBi:Liq was formed on the assistance layer, and a cathode of Al was formed on the assistance layer to manufacture an organic light emitting device.

### Experimental Example 2

An organic light emitting device was manufactured by the same method as Experimental Example 1, except that the assistance layer was 26DCzPPy.

### Experimental Example 3

An organic light emitting device was manufactured by the same method as Experimental Example 1, except that the assistance layer was CBzCBI:Liq.

### Experimental Example 4

An organic light emitting device was manufactured by the same method as Experimental Example 1, except that the assistance layer was CBzCBI:TPBi.

### Comparative Example

An organic light emitting device was manufactured by the same method as Experimental Example 1, except that the assistance layer was omitted between the emission layer and the electron transport layer.

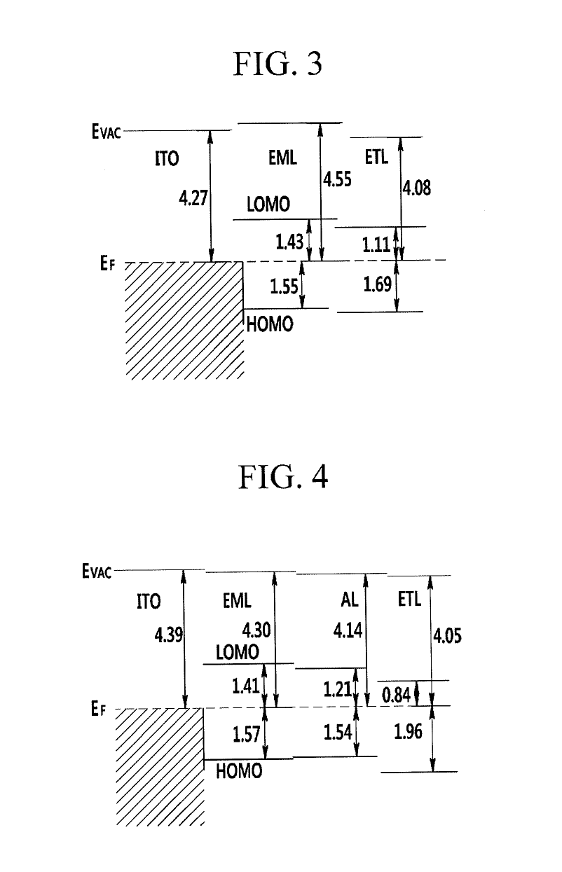

The energy level between the layers of the organic light emitting devices according to the comparative example and Experimental Example 1 was measured using ultraviolet photoelectron spectroscopy (UPS) and UV-visible spectroscopy. FIG. 3 illustrates an energy level relationship for the organic light emitting device of the comparative example, and FIG. 4 illustrates an energy level relationship for the organic light emitting device of Experimental Example 1.

In FIG. 3, referring to the HOMO level of the emission layer EML and the electron transport layer ETL, the HOMO level of the emission layer was higher than the HOMO level of the electron transport layer by 0.14 eV, and the LUMO level of the emission layer was higher than the LUMO level of the electron transport layer by 0.32 eV. Accordingly, the gap of the HOMO level therebetween was 0.14 eV.

In FIG. 4, the assistance layer (AL) was formed between the emission layer EML and the electron transport layer ETL, and the HOMO level of the assistance layer was higher than the HOMO level of the electron transport layer by 0.42 eV. As the gap of the HOMO level is increased, it is increasingly difficult for the holes to flow over into the electron transport layer. As such, the accumulation of holes in the electron transport layer may be reduced or may be substantially prevented.

In FIG. 4, referring to the energy relationship of the emission layer and the assistance layer, the former HOMO level was higher than the latter HOMO level by 0.03 eV, however there was not a large difference. In the LUMO level, the emission layer was higher than the assistance layer by 0.2 eV, and the electron transport layer was lower than the assistance layer by 0.37 eV.

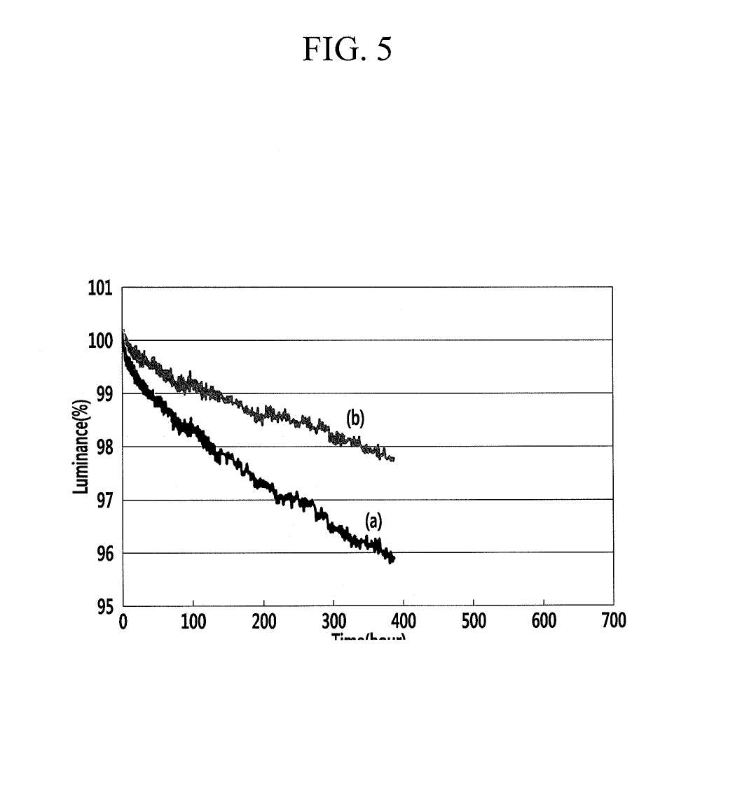

FIG. 5 to FIG. 9 illustrate views showing the lifetime of the organic light emitting device manufactured according to the described experimental examples and the organic light emitting device manufactured according to the comparative example, that is, a luminance deterioration over a driving time. In each drawing, the organic light emitting device of the comparative example is indicated by (a), and the organic light emitting device of each experimental example is indicated by (b).

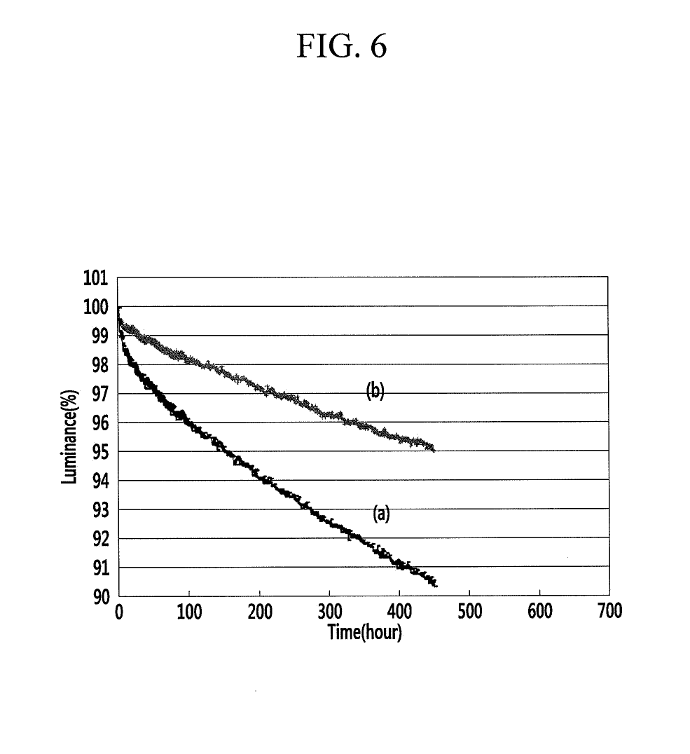

Referring to FIG. 5 and FIG. 6, the luminance deterioration over driving time of the organic light emitting device of Experimental Example 1 with the assistance layer of CBzCBI is shown along with that for the organic light emitting device of the comparative example in a graph. Here, FIG. 5 illustrates results obtained while driving the organic light emitting device at room temperature, and FIG. 6 illustrates results obtained by driving the organic light emitting device at a high temperature (50° C.).

As shown in FIG. 5, when the organic light emitting device was driven at room temperature for about 300 hours, the organic light emitting device (a) of the comparative example exhibited a decrease in luminance of about 4%, from 100% to about 96%. In contrast, for the organic light emitting device (b) of Experimental Example 1, the luminance decreased by about 2%, from 100% to about 98%. Also, as shown in FIG. 6, the organic light emitting device was driven at the high temperature for about 400 hours, the organic light emitting device (a) of the comparative example exhibited a decrease in luminance of about 9% to about 91%. In contrast, for the organic light emitting device (b) of Experimental Example 1, the luminance decreased by about 4.5% to about 95.5%. Accordingly, for the organic light emitting device (b) according to Experimental Example 1 compared with the organic light emitting device (a) of the comparative example, the lifetime increased by more than about two times at the high temperature as well as at room temperature.

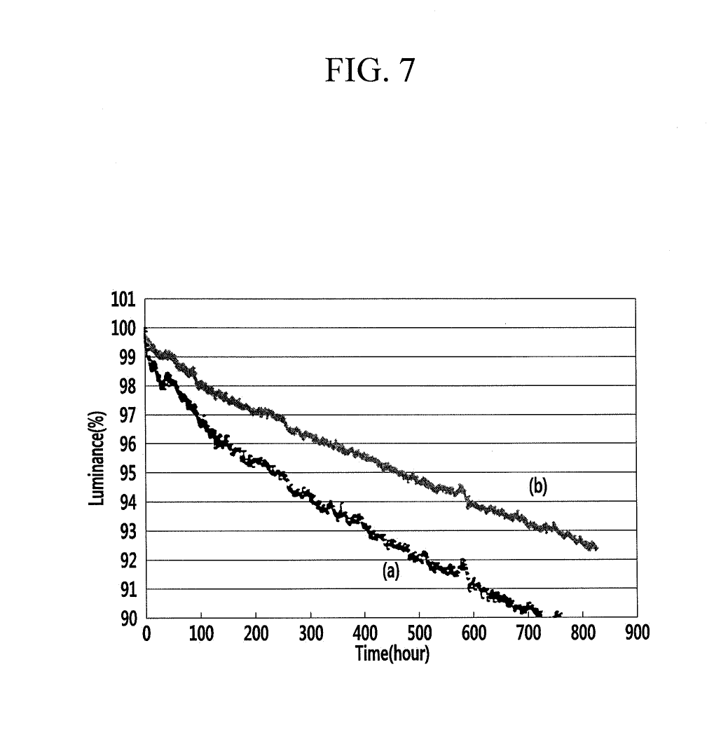

FIG. 7 illustrates a graph showing an increase of the lifetime of the organic light emitting device (b) according to Experimental Example 2 with the assistance layer of 26DCzPPy. The organic light emitting device (b) was driven at room temperature and measured along with the organic light emitting device (a) according to the comparative example. When driven for about 300 hours, the luminance decreased to about 94% for the organic light emitting device (a) of the comparative example. In contrast, the luminance of the organic light emitting device (b) according to Experimental Example 2 was over 96% such that the luminance difference was about 2.5%, and the luminance difference increased as the driving time increased.

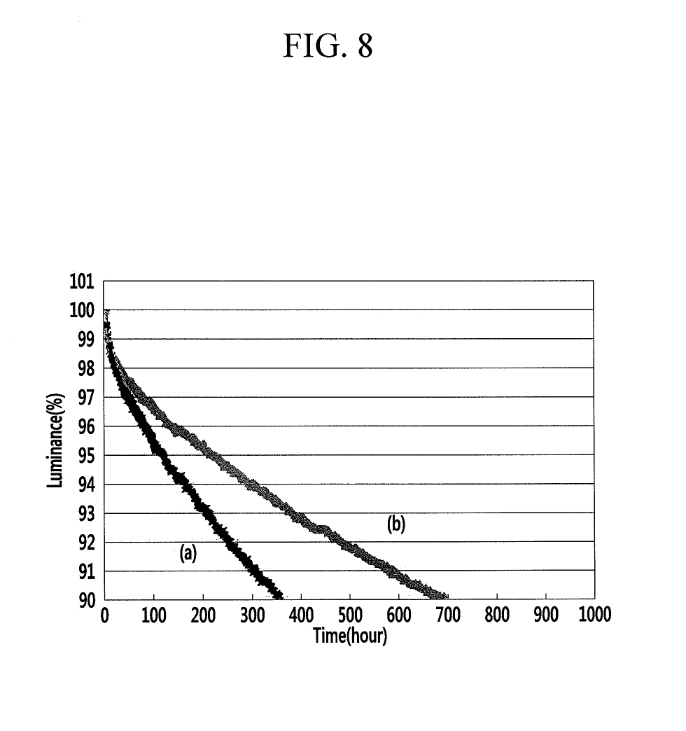

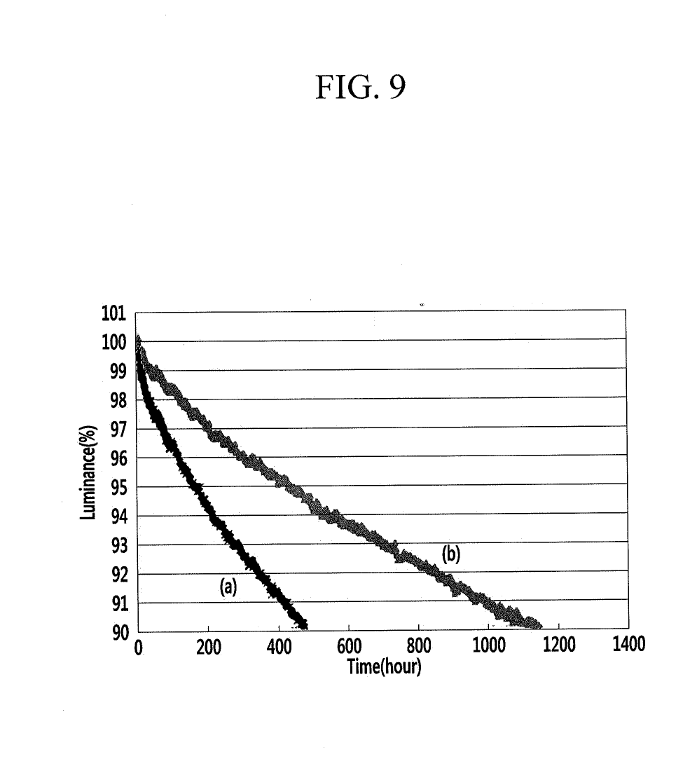

FIG. 8 and FIG. 9 illustrate results obtained from driving the organic light emitting device (b) according to Experimental Example 3 in which Liq is co-deposited with CBzCBI when forming the assistance layer, and the organic light emitting device (b) according to Experimental Example 4 in which TPBi is co-deposited with CBzCBI at the high temperature of 50° C. In each figure, the component (a) represents the organic light emitting device according to the comparative example, and shows the results when the organic light emitting device was driven at the high temperature of 50° C.

As shown in FIG. 8 and FIG. 9, it took about two or more times longer for the luminance of 100% to be decreased to the luminance of 90% in the organic light emitting device (b) according to Experimental Examples 3 and 4 as compared with the organic light emitting device (a) according to the comparative example.

Thus, the results from the experimental examples demonstrate that by forming the assistance layer between the emission layer and the electron transport layer to increase the gap of the HOMO level, the lifetime of the organic light emitting device may be remarkably and unexpectedly increased.

By way of summation and review, organic light emitting devices may include two electrodes facing each other, and an organic layer interposed between the electrodes. In the organic light emitting diode, if holes injected from an anode and electrons injected from a cathode meet each other at a light emitting layer to generate excitons, and the excitons are subjected to photo-luminescent quenching, light may be generated. Organic light emitting device may be employed in various fields including display devices and lighting devices.

Various causes reduced lifetime in organic light emitting devices are known. One of these causes may be that the electron transport layer may lose its characteristic as an electron transport layer because holes may accumulate in the electron transport layer when the organic light emitting device is driven.

In contrast, exemplary embodiments provide an organic light emitting device having a reduced accumulation of holes in an electron transport layer and an increased lifetime. In exemplary embodiments, hole accumulation may be reduced or prevented in the electron transport layer by the gap of the HOMO level between the assistance layer and the electron transport layer such that the lifetime of the organic light emitting device may be increased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

### DESCRIPTION OF SYMBOLS

| | |
|---|---|
| 100: anode | 210: hole injection layer |
| 220: hole transport layer | 230: emission layer |
| 240: assistance layer | 250: electron transport layer |
| 260: electron injection layer | 300: cathode |

What is claimed is:

1. An organic light emitting device comprising:
an anode, a cathode, and an organic layer between the anode and the cathode,
wherein:
the organic layer includes an emission layer, an electron transport layer, and an assistance layer interposed between the emission layer and the electron transport layer, and
the assistance layer has a HOMO level more than 0.3 eV higher than a HOMO level of the electron transport layer.

2. The organic light emitting device as claimed in claim 1, wherein
the assistance layer includes at least one of 26DCzPPy (2,6-bis(3-(9H-carbazol-9-yl)phenyl)pyridine) and CBzCBI (9-phenyl-3-(4-(1-phenyl-1H-benzo[d]imidazol-2-yl)phenyl)-9H-carbazole).

3. The organic light emitting device as claimed in claim 1, wherein
the assistance layer is doped with at least one dopant in a ratio of about 5 to about 95% by weight.

4. The organic light emitting device as claimed in claim 3, wherein
the dopant is selected from a group including TPBi (2,2′,2″-(1,3,5-benzinetriyl)-tris(1-phenyl-1-H-benzimidazole)), Liq (8-hydroxyquinolinolato-lithium), NBphen (2,9-bis(naphthalen-2-yl)-4,7-diphenyl-1,10-phenanthroline), 2-NPIP (1-methyl-2-(4-(naphthalen-2-yl)phenyl)-1H-imidazo[4,5f][1,10]phenanthroline), and TmPPPyTz (2,4,6-tris(3′-(pyridin-3-yl)biphenyl-3-yl)-1,3,5-triazine).

5. The organic light emitting device as claimed in claim 1, wherein
the organic layer further includes a hole injection layer and a hole transport layer between the anode and the emission layer.

6. The organic light emitting device as claimed in claim 5, wherein
the organic layer further includes an electron injection layer between the cathode and the electron transport layer.

7. The organic light emitting device as claimed in claim 1, wherein
the assistance layer has a higher LUMO level than a LUMO level of the electron transport layer.

8. The organic light emitting device as claimed in claim 1, wherein
the assistance layer has a lower LUMO level than a LUMO level of the emission layer.

9. The organic light emitting device as claimed in claim 1, wherein
the assistance layer has lower hole mobility than the emission layer.

10. A method of manufacturing an organic light emitting device, comprising:
forming an anode on a substrate;
forming a hole injection layer and a hole transport layer on the anode;
forming an emission layer on the hole transport layer;
forming an assistance layer on the emission layer;
forming an electron transport layer on the assistance layer; and
forming a cathode on the electron transport layer,
wherein the assistance layer has a HOMO level more than 0.3 eV higher than a HOMO level of the electron transport layer.

11. The method of manufacturing as claimed in claim 10, wherein
the assistance layer is separately formed before the forming of the electron transport layer.

12. The method of manufacturing as claimed in claim 10, wherein
forming the assistance layer includes forming the assistance layer from a portion of the electron transport layer by initially doping a portion of the electron transport layer with a dopant.

13. The method of manufacturing as claimed in claim 12, wherein
the dopant is selected from a group including TPBi (2,2′,2″-(1,3,5-benzinetriyl)-tris(1-phenyl-1-H-benzimidazole)), Liq (8-hydroxyquinolinolato-lithium), NBphen (2,9-bis(naphthalen-2-yl)-4,7-diphenyl-1,10-phenanthroline), 2-NPIP (1-methyl-2-(4-(naphthalen-2-yl)phenyl)-1H-imidazo[4,5f][1,10]phenanthroline), and TmPPPyTz (2,4,6-tris(3′-(pyridin-3-yl)biphenyl-3-yl)-1,3,5-triazine).

14. The method of manufacturing as claimed in claim 10, further comprising forming an electron injection layer before forming the cathode.
